(19) United States
(12) Patent Application Publication
(10) Pub. No.: US 2025/0385646 A1
(43) Pub. Date: Dec. 18, 2025

(54) AUDIO AMPLIFIER CIRCUIT FOR DRIVING A SPEAKER

(71) Applicant: Renesas Design Netherlands B.V., 's-Hertogenbosch (NL)

(72) Inventor: Marinus Wilhelmus KRUISKAMP, ‘s-Hertogenbosch (NL)

(73) Assignee: Renesas Design Netherlands B.V., 's-Hertogenbosch (NL)

(21) Appl. No.: 18/743,281

(22) Filed: Jun. 14, 2024

(51) Int. Cl. H03F 1/26; H03F 1/02; H03F 3/213; H03F 3/217

(52) U.S. Cl. CPC H03F 1/26; H03F 1/0205; H03F 3/213; H03F 3/217; H03F 2200/03; H03F 2200/331; H03F 2200/351

(57) ABSTRACT

An audio amplifier circuit is provided. The circuit includes a reference PWM unit for generating a reference PWM signal based on a to-be-rendered audio signal, and a drive PWM unit that generates a drive PWM signal for driving a speaker based on a corrected signal. The corrected signal is dependent on the to-be-rendered audio signal. The circuit also includes an oscillator for adapting an oscillator frequency in dependence of an error signal. The error signal is dependent on the reference PWM signal and on the drive PWM signal. The circuit further includes a counter for determining a cumulated counter value based on oscillator cycles of the oscillator. The circuit also includes a digital loop filter for generating a correction signal for determining the corrected signal based on the cumulated counter value.

### TECHNICAL FIELD

The present document relates to a closed-loop class-D audio amplifier, especially for driving a speaker of an in-ear headset.

### BACKGROUND

An audio headset typically comprises an amplifier which is configured to amplify an audio signal and to drive a speaker for rendering the amplified audio signal.

The present document addresses the technical problem of reducing the power consumption and the size for such an amplifier, in order to facilitate the integration of such an amplifier within relatively small headsets, such as in-ear headsets. The technical problem is solved by each one of the independent claims. Preferred examples are described in the dependent claims.

### SUMMARY

According to an aspect, an audio amplifier circuit comprising a reference PWM unit (e.g., reference PWM circuit) configured to generate a reference PWM signal based on a to-be-rendered audio signal, and a drive PWM unit (e.g., drive PWM circuit) configured to generate a drive PWM signal for driving a speaker based on a corrected signal is described, wherein the corrected signal is dependent on the to-be-rendered audio signal. The audio amplifier circuit further comprises an oscillator (e.g., a voltage or current controlled oscillator, notably a ring oscillator) which is configured to adapt an oscillator frequency in dependence of an error signal, wherein the error signal is dependent on the reference PWM signal and on the drive PWM signal. In addition, the audio amplifier circuit comprises a counter configured to determine a cumulated counter value based on oscillator cycles of the oscillator, and a digital loop filter configured to generate a correction signal for determining the corrected signal, based on the cumulated counter value.

According to another aspect, a method for driving a speaker is described. The method comprises generating a reference PWM signal based on a to-be-rendered audio signal using a reference PWM unit, and generating a drive PWM signal for driving the speaker based on a corrected signal using a drive PWM unit, wherein the corrected signal is dependent on the to-be-rendered audio signal. Furthermore, the method comprises adapting an oscillator frequency of an oscillator (e.g., a voltage or current controlled oscillator, notably a ring oscillator) in dependence of an error signal, wherein the error signal is dependent on the reference PWM signal and on the drive PWM signal. The method further comprises determining a cumulated counter value based on oscillator cycles of the oscillator using a counter, and generating a correction signal for determining the corrected signal, based on the cumulated counter value, using a loop filter.

It should be noted that the methods and systems including its preferred embodiments as outlined in the present document may be used stand-alone or in combination with the other methods and systems disclosed in this document. In addition, the features outlined in the context of a system are also applicable to a corresponding method. Furthermore, all aspects of the methods and systems outlined in the present document may be arbitrarily combined. In particular, the features of the claims may be combined with one another in an arbitrary manner.

### BRIEF DESCRIPTION OF THE FIGURES

The disclosure is explained below in an exemplary manner with reference to the accompanying drawings, wherein

FIG. 1A illustrates an open-loop class D audio amplifier;

FIG. 1B shows a differential PWM signal for driving a speaker;

FIG. 2 shows an amplifier circuit comprising a high order sigma delta converter;

FIG. 3 shows an amplifier circuit comprising a ring oscillator (as an example for a voltage or current controlled oscillator);

FIG. 4 shows an example audio amplifier circuit comprising a feedback loop with a ring oscillator; and

FIG. 5 shows a flow chart of an example method for driving a speaker for rendering an audio signal.

### DETAILED DESCRIPTION

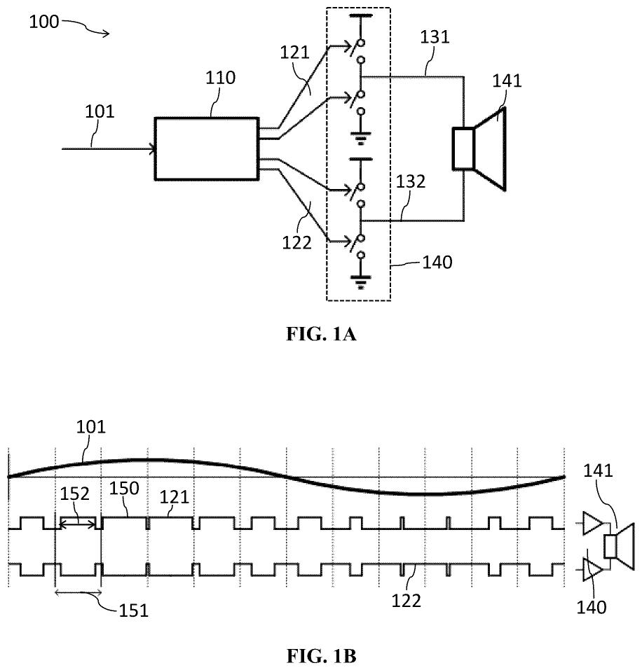

As indicated above, the present document is directed at providing an amplifier circuit, notably a class D amplifier circuit, with relatively low distortion, reduced power consumption and a high fraction of digital circuitry. In this context, FIG. 1A shows an open-loop class-D audio amplifier circuit 100 which is configured to generate, in a digital manner, a PWM (pulse width modulation) signal 121, 122 that controls switches (i.e. buffers) 140 to drive a speaker 141. The amplifier circuit 100 comprises a PWM generator 110 which is configured to generate a differential PWM signal 121, 122 (based on the audio signal 101 that is to be rendered) with a first PWM signal (i.e. a first component) 121 and a second PWM signal (i.e. a second component) 122. The second PWM signal 122 may be equal to or may be the inverted version of the first PWM signal 121. The PWM generator 110 is operated at a certain PWM frequency (e.g., 3 MHz), such that the PWM signal 121, 122 comprises PWM pulses at the PWM frequency. The switches 140 are configured to amplify the PWM signal 121, 122, thereby providing a (differential) drive PWM signal 131, 132 for driving the speaker 141.

FIG. 1B shows an example audio signal 101 and a corresponding differential PWM signal 121, 122. It can be seen that the PWM signal 121, 122 comprises a sequence of pulses 150, one pulse 150 per PWM period 151 (which is the inverse of the PWM frequency). The duration 152 of the individual pulses 150 is varied, in order to approximate the original audio signal 101. The duration 152 may be varied with a certain resolution. The resolution is typically limited to a certain number N of bits, e.g. N=5 bits, thereby allowing 2^{N} different durations 152 ranging from 0 up to the PWM period 151.

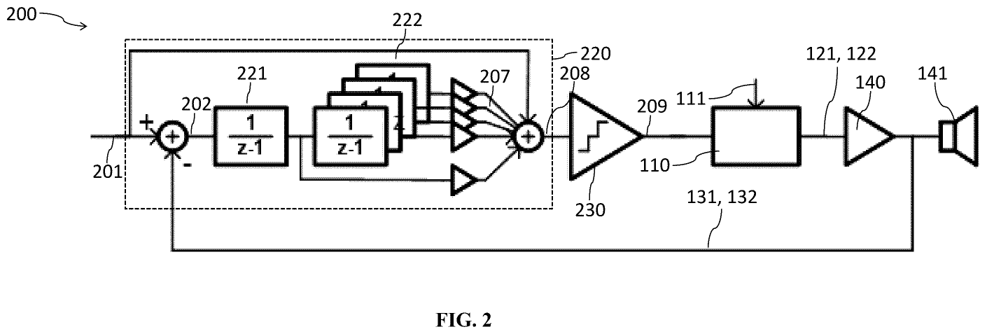

The on-resistance of the switches 140 and noise on the supply voltage of the switches 140 typically add distortion and noise to the audio signal. To reduce this noise and distortion, a feedback of the (analog) drive PWM signal 131, 132 of the speaker 141 to the PWM generator 110 may be used, as illustrated e.g. in FIG. 2.

In the amplifier circuit 200 of FIG. 2, The audio signal 101 may be converted into or may be provided as a digital signal 201. The drive PWM signal 131, 132 for driving the speaker 141 may be subtracted from the sampled audio signal 201 to generate an error signal 202. Due to the fact that the drive PWM signal 131, 132 is an analog signal, the drive PWM signal 131, 132 typically needs to be converted into a digital signal before generating the error signal 202. This requires the use of an analog-to-digital converter which is typically quite large and which typically exhibits a relatively large power consumption.

The error signal 202 may be used to generate a correction signal 207 for correcting the sampled audio signal 201. The correction signal 207 may be derived from the error signal 202 using one of more integrators 221, 222. By using a relatively high number of integrators 221, 222, the noise of the amplifier circuit 200, which lies within the audible frequency range, can be reduced.

The corrected signal 208 may be quantized using a quantization unit 230, thereby providing a quantized signal 209 which may be used to derive the PWM signal 121, 122 using the PWM generator 110.

The sampling frequency 211 typically corresponds to the PWM frequency, i.e. the processing shown in FIG. 2 is performed once per PWM period 151. The PWM signal 121, 122 may have a temporal resolution which depends on the clock frequency (with which the switches 140 may be driven).

When implementing a closed-loop amplifier circuit 200 in a time-discrete digital manner (as shown in FIG. 2), the temporal resolution of the PWM signal 121, 122 is limited by the clock frequency of the digital system. By way of example, the clock frequency may only be 32 times (i.e. 2^{N} times) higher than the PWM frequency 211, therefore limiting the PWM resolution to a relatively low number N of bits. As shown in FIG. 2, a loop filter 220 may be used to shape the quantization noise for converting the high-resolution input signal 101 to a low-resolution quantized signal 209 from which the PWM signal 121, 122 is generated. If a first order loop filter 220 (which comprises only a single integrator 221 in the loop) is used a relatively high number N of bits resolution would be needed at the output to reduce the quantization noise to a sufficiently low level in order to meet the specification for an audio amplifier. By making use of a higher-order loop filter 220 (comprising the main integrator 221 and one or more additional integrators 222) as part of the sigma delta converter the quantization noise (within the audible frequency range) can be reduced to meet the audio specification.

It is relatively efficient (in terms of area and power consumption) to implement a high-order loop filter 220 in the digital domain. However, as illustrated in FIG. 2, the drive PWM signal 131, 132 (which is an analog signal) is to be integrated into the feedback loop, in order to suppress the negative effects of driver resistance and supply noise. A high-order loop filter 220 in the analog domain is relatively expensive (in terms of area and power consumption).

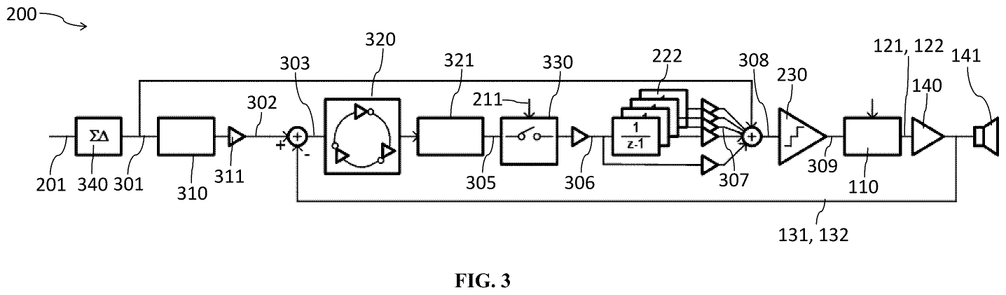

FIG. 3 shows a closed-loop audio amplifier 200 which makes use of a ring oscillator 320 as part of the main integrator 221. In particular, the main integrator 221 in the loop filter 220 may be replaced by a ring oscillator 320 plus a counter 321. A ring oscillator 320 converts a voltage to a high frequency (e.g. in the range of 1 or more GHz). The counter 321 integrates the frequency, thereby resulting in a digital value (i.e. a cumulated counter value) which is proportional to the integrated voltage. The resolution of the counter 321 may be relatively high, since the counter 321 is driven by the frequency of the ring oscillator 320 and not by the clock frequency of the system.

From the counter 321 onwards, the signal is digital, meaning that the signal can be processed further in an efficient manner to provide a low-resolution signal 309 which is needed for the PWM generation.

The amplifier circuit 200 of FIG. 3 comprises a sample-and-hold unit 210 (with a sampling frequency 211) which is configured to generate a sampled audio signal 201 based on the input audio signal 101. The sampled audio signal 201 comprises a sequence of sample values of the input audio signal 101 at the sampling frequency 211 (which typically is equal to the PWM frequency of the PWM signal 121, 122).

The sampled (digital) audio signal 201 may be converted into a digital time-discrete input signal 301 (having a relatively low amplitude resolution, with N bits) using a converter 340 (notably a sigma-delta converter). The digital input signal 301 comprises a sequence of digital values at the sampling frequency 211, wherein the digital values have a resolution of N bits.

Using a first PWM generator 310 (and an amplifier or buffer 311), the digital input signal 301 may be converted into a reference PWM signal 302. Wherein the reference PWM signal 302 has a relatively low resolution of N bits (e.g. N=5). The amplifier 311 applies an amplification factor which corresponds to the amplification factor which is applied by the drive buffer 140. The (analog) drive PWM signal 131, 132 is subtracted from the reference PWM signal 302 to generate an error signal 303, wherein the error signal 303 is used to generate a correction signal 307 for correcting the digital input signal 301, thereby providing a corrected input signal 308. The corrected input signal 308 is quantized within the quantization unit 230, and the quantized signal 309 is used to generate the PWM signal 121, 122. The processing is performed repeatedly for each PWM period 151.

The ring oscillator 320 is controlled by the error signal 303. In particular, the ring oscillator 320 may be configured to vary the oscillator frequency in dependence of the error signal 303. Hence, the rate of oscillator cycles increases if the error signal 303 increases and decreases if the error signal 303 decreases. It should be noted that the ring oscillator 320 is an example for a generic voltage or current controlled oscillator (VCO or CCO). The aspects which are described herein with regards to a “ring oscillator” are applicable in general to a “voltage or current controlled oscillator”.

The counter 321 is configured to count the number of oscillator cycles of the ring oscillator 320, thereby integrating the error signal 303, i.e. thereby providing an integrated error signal 305. The integrated error signal 305 may be converted into a sampled signal (at the sampling frequency 211) using a sample-and-hold unit 330, wherein the sampled signal may be processed in the digital domain using one or more additional integrators 222, thereby providing the correction signal 307.

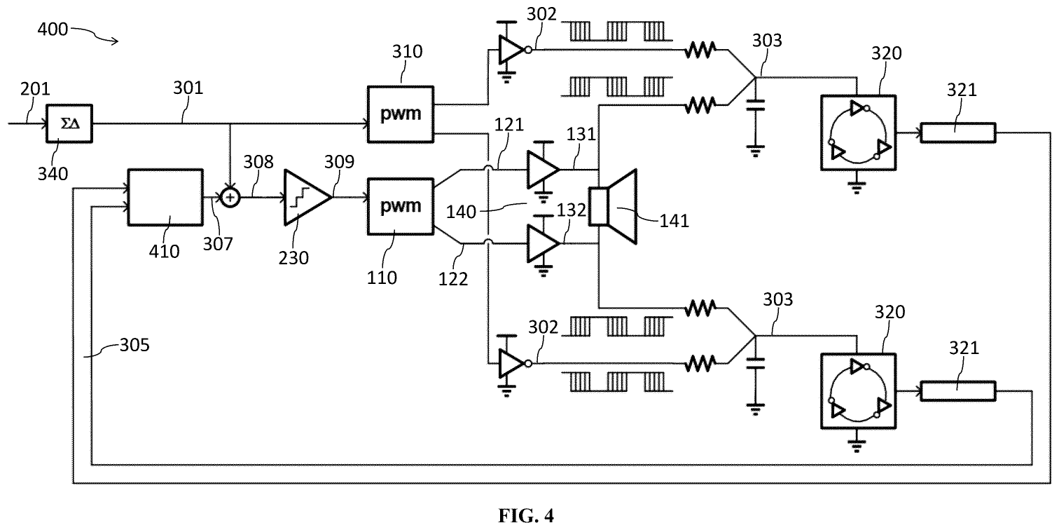

It should be noted that in FIG. 3 (and in FIG. 2), the processing of both PWM signals 121, 122 is shown within a single feedback loop. The processing may be performed separately for each PWM signal 121, 122, i.e. for each component of the PWM signal 121, 122 (as shown in FIG. 4).

Hence, an amplifier circuit 200, 400 may be provided, which is mainly digital, with the ring oscillator 320 being the only analog circuit. The first quantization occurs in the counter 321 (subsequent to a single integrator, i.e. a first order integrator), however the quantization may occur at a relatively high resolution due to the relatively high oscillator frequency (e.g. of 1 GHz or more) of the ring oscillator 320. Therefore, this quantization meets the noise requirements.

The second quantization occurs in the digital domain (within the quantization unit 230) and is performed subsequent to a loop filter (wherein the loop filter may comprise a cascade of one or more integrators 222). As a result of this, noise requirements are met (within the audible range), even if the output of the quantization is only a relatively now number N of bits.

A possible performance limitation, which is caused by the non-linearity of the ring oscillators 320 (for converting voltage (i.e., the error signal 303) to frequency), may be overcome or at least improved by a differential circuit and by subtraction of the digital input signal 301 (which is the wanted output signal) from the actual drive PWM signal 131, 132 at the speaker 141, notably in such a way that the supply voltage of the ring oscillator(s) 320 is substantially constant.

The amplifier circuit 400 of FIG. 4 may comprise the following components:
A relatively low-resolution digital input signal 301 (e.g. N=5 bits) at a relatively high sampling frequency 211 (e.g. 3.072 MHz) is provided.
A digital PWM generator 310 (e.g. with a clock frequency of 98.304 MHz) configured to convert the low-resolution digital input signal 301 into a differential reference PWM signal 302. This is the inverted desired output signal.
A PWM generator 110 (similar or equal to PWM generator 310) configured to generate the differential PWM signal 121, 122 for driving the speaker 141. The low-resolution input signals of the PWM generator 110 and the PWM generator 310 are typically similar, or slightly different, in order to compensate for the unwanted effects caused by the output resistance and/or the supply voltage variation.
A quantization unit 230 to generate a low-resolution signal to drive the PWM generator 110.
A digital loop filter 410 which processes the feedback signals (using one or more additional integrators 222).
A summation to determine the corrected signal 308 based on the digital input signal 301 and based on the correction signal 307.
Two ring oscillators 320. The supply voltage of a ring-oscillator 320 may be the input signal, the phase of the ring oscillator 320 may be the output signal. The phase can be measured in complete cycles, or in a finer resolution (like 5 complete cycles+⅓ fractional cycle). One ring-oscillator 320 is monitoring the positive terminal of the speaker (i.e., the first component 131), the other ring oscillator 320 is monitoring the negative terminal of the speaker (i.e., the second component 132).
Resistors may be used, which connect the speaker output, i.e. the drive PWM signal, 131, 132 plus the inverted wanted output signal 302 (i.e., the error signal 303) to the supply of the ring oscillators 320. In the ideal case, the speaker output 131, 132 plus the inverted wanted signal 302 will be constant, averaged over a PWM period 151.
Counters 321 to measure the phase (i.e., the number of cycles) of the ring oscillators 320. The frequency of the ring oscillators 320 is typically proportional to its supply voltage. The phase is equal to the frequency integrated over time. As a result of this, the counter value is proportional to the supply voltage of the ring oscillator, integrated over time.
Optional capacitors to low-pass filter the supply voltage (i.e. the error signal 303) for the ring oscillators 320. This reduces the voltage swing at the supply of the ring oscillators 320, which reduces the negative effect from non-linearity in the voltage to frequency relation of the ring-oscillators 320.
Buffers 140 to drive the speaker 141. Each buffer 140 may comprise a switch to ground and a switch to the supply (as illustrated in FIG. 1A).
Inverters to provide the (inverted) wanted reference PWM signal 302. The inverters may each comprise a switch to ground and a switch to the supply.

The power consumption may be reduced by only driving the speaker 141 and the reference PWM signal 302 at the moments close to the edges of the PWM signal. To keep the ring oscillators 320 running at an as constant as possible frequency, the power the ring oscillators 320 may be set differently during the floating periods.

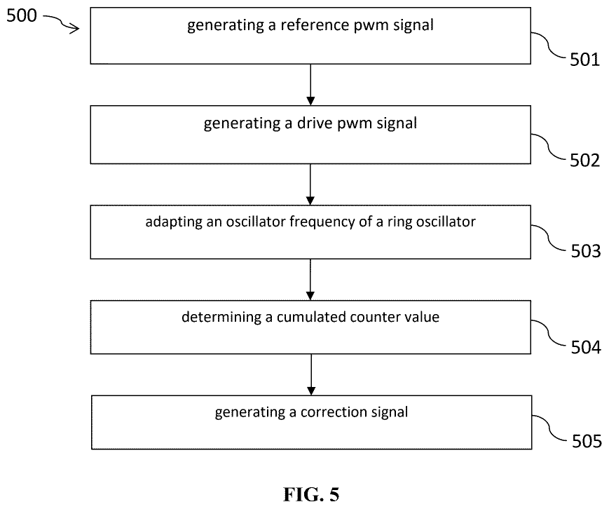

FIG. 5 shows a flow chart of an example method 500 for driving a speaker 141 in dependence of a to-be-rendered audio signal 101. In particular, the speaker 141 may be driven to render the to-be-rendered audio signal 101. The to-be-rendered audio signal 101 may have a relatively high resolution (e.g., 8 bits or more, or 16 bits or more). Furthermore, the to-be-rendered audio signal 101 may have a certain sampling frequency (e.g. 400 kHz or less, e.g. a multiple of 48 kHz such as 48 kHz, 96 kHz, 192 kHz, 384 kHz or a multiple of 44.1 kHz such as 44.1 kHz, 88.2 kHz).

The method 500 comprises generating 501 a reference PWM signal 302 based on the to-be-rendered audio signal 101 using a reference PWM unit 310. The sampling frequency of the reference PWM signal 302 may be higher than the sampling frequency of the to-be-rendered audio signal 101 (e.g., 100 kHz or more, or 1 MHz or more). On the other hand, the resolution of the reference PWM signal 302 may be lower than the resolution of the to-be-rendered audio signal 101 (e.g., 8 bits or less, or 6 bits or less). The reference PWM signal 302 may be taken as a reference of the audio signal 101 that is to be rendered.

The method 500 further comprises generating 502 a drive PWM signal 131, 132 for driving the speaker 141 based on a corrected signal 308 using a drive PWM unit 110, 140, wherein the corrected signal 308 is dependent on the to-be-rendered audio signal 101. The drive PWM signal 131, 132 and the reference PWM signal 302 may be substantially equal, apart from differences which are caused by a correction signal 307 (that is used to determine the corrected signal 308). The correction signal 307 may be used to compensate noise and/or distortions that are caused by driving the speaker 141 when rendering the to-be-rendered audio signal 101 using a PWM signal 131, 132.

Furthermore, the method 500 comprises adapting 503 the oscillator frequency of a voltage or current controlled oscillator 320 in dependence of an error signal 303, wherein the error signal 303 is dependent on the reference PWM signal 302 and on the drive PWM signal 131, 132. In particular, the error signal 303 may be dependent on the deviation of the drive PWM signal 131, 132 from the reference PWM signal 302. The voltage or current controlled oscillator 320 may be used to convert the level of the error signal 303 into a value of the oscillator frequency. An increase of the level of the error signal 303 may lead to an increase of the oscillator frequency (and by consequence to an increase of the number of oscillator cycles). On the other hand, a decrease of the level of the error signal 303 may lead to a decrease of the oscillator frequency (and by consequence to a decrease of the number of oscillator cycles).

In addition, the method 500 comprises determining 504 a cumulated counter value 305 based on the oscillator cycles of the voltage or current controlled oscillator 320 using a counter 321. The cumulated counter value 305 may be indicative of the cumulated level of the error signal 303. Hence, a voltage or current controlled oscillator 320 and a subsequent counter 321 may be used to integrate the error signal 303 (using the voltage or current controlled oscillator 320 as an analog circuit). The subsequent processing of the cumulated counter value 305 (e.g. using one or more additional integrators 222) may be performed in the digital domain.

The method 500 further comprises generating 505 the correction signal 307 for determining the corrected signal 308, based on the cumulated counter value, using a loop filter 410 (wherein the loop filter 410 may comprise one or more additional digital integrators 222).

Using the described method 500, an audio signal 101 may be rendered in an efficient manner at a high audio quality.

Hence, an audio amplifier circuit 400 is described, which comprises a reference PWM unit 310 configured to generate a reference PWM signal 302 based on a to-be-rendered audio signal 101. The audio amplifier circuit 400 may comprise a converter 210, 340 which is configured to generate a digital input signal 301 at a sampling frequency 211 and at an amplifier resolution, based on the to-be-rendered audio signal 101. The reference PWM unit 310 may be configured to generate the reference PWM signal 302 based on the digital input signal 301.

The converter 210, 340 may comprise a sample-and-hold unit 210 which is configured to generate a sampled signal 201 based on the to-be-rendered audio signal 101, wherein the sampled signal 201 exhibits the sampling frequency. Furthermore, the converter 210, 340 may comprise a sigma-delta converter 340 which is configured to generate the digital input signal 301 based on the sampled signal 201. Hence, the amplifier circuit 400 may be configured to provide a digital input signal 301 for the (and based on the) to-be-rendered audio signal 101.

The to-be-rendered audio signal 101 typically exhibits a resolution which is at least two times higher than the amplifier resolution. Furthermore, the sampling frequency 211 of the digital input signal 301 is typically at least two times higher than the frequency that the to-be-rendered audio signal 101 is sampled at.

Hence, a converter may be used which is configured to increase the sampling frequency and reduce the resolution, to provide a digital input signal 301 (with an increased sampling frequency and a reduced resolution) as a representation of the to-be-rendered audio signal 101. The digital input signal 301 may be used to generate the reference PWM signal 302 as a PWM representation of the to-be-rendered audio signal 101.

In a preferred example, the reference PWM unit 310 is configured to generate a differential reference PWM signal 302 (comprising a first (positive) component and a second (negative) component, wherein the first component and the second component are typically inverted versions of one another).

The audio amplifier circuit 400 further comprises a drive PWM unit 110, 140 which is configured to generate a drive PWM signal 131, 132 for driving a speaker 141 based on a corrected signal 308, wherein the corrected signal 308 is dependent on the to-be-rendered audio signal 101. The audio amplifier circuit 400 may comprise a correction unit which is configured to determine the corrected signal 308 based on a correction signal 307 and based on the digital input signal 301. In particular, the corrected signal 308 may be determined based on the sum or the difference of the correction signal 307 and the digital input signal 301.

Hence, the speaker 141 may be driven based on a corrected version of the digital input signal 301. The correction signal 307, which is used for correcting the digital input signal 301, may be used for compensating for noise and/or distortions that are caused by the audio amplifier circuit 400 when rendering the audio signal 101. The correction signal 307 may be determined using a feedback loop which feeds back and/or compares the drive PWM signal 131, 132 to or with the reference PWM signal 302.

The audio amplifier circuit 400 may comprise a quantization unit 230 configured to generate a quantized signal 309 based on the corrected signal 308. The quantized signal 309 may be sampled at the sampling frequency 211 and may have the amplifier resolution. The drive PWM unit 110 may be configured to generate the drive PWM signal 131, 132 based on the quantized signal 309.

In a preferred example, the drive PWM unit 110, 140 is configured to generate a differential drive PWM signal 131, 132 (comprising a first (positive) component and a second (negative) component, wherein the first component and the second component are typically inverted versions of one another).

The audio amplifier circuit 400 further comprises a voltage or current controlled oscillator 320 (notably a ring oscillator) which is configured to adapt its oscillator frequency in dependence of an error signal 303, wherein the error signal 303 is dependent on the reference PWM signal 302 and on the drive PWM signal 131, 132. The audio amplifier circuit 400 may comprise a combination unit which is configured to determine the error signal 303 based on the reference PWM signal 302 and based on the drive PWM signal 131, 132, in particular based on the difference of the reference PWM signal 302 and the drive PWM signal 131, 132.

Furthermore, the audio amplifier circuit 400 comprises a counter 321 which is configured to determine a cumulated counter value 305 based on the (number of) oscillator cycles of the voltage or current controlled oscillator 320. Each oscillator cycle may lead to an increase of the cumulated counter value 305. The voltage or current controlled oscillator 320 may vary the oscillator frequency (and by consequence the rate of the oscillator cycles) in dependence of the level of the error signal 303. By consequence, the cumulated counter value 305 may be an indication of the cumulated or integrated error signal 303.

In case of differential PWM signals, the error signal 303 may be a differential signal comprising a first component and a second component. The audio amplifier circuit 400 may comprise a first voltage or current controlled oscillator 320 (notably a first ring oscillator) and a first counter 321 for the first component of the error signal 303 and a second voltage or current controlled oscillator 320 (notably a second ring oscillator) and a second counter 321 for the second component of the error signal 303. The first voltage or current controlled oscillator 320 and the first counter 321 may be configured to provide a first cumulated counter value 305 based on the first component of the error signal 303, and the second voltage or current controlled oscillator 320 and the second counter 321 may be configured to provide a second cumulated counter value 305 based on the second component of the error signal 303.

Furthermore, the audio amplifier circuit 400 may comprise a digital loop filter 410 which is configured to generate the correction signal 307 for determining the corrected signal 308, based on the cumulated counter value. In particular, the loop filter 410 may be configured to generate the correction signal 307 based on the first cumulated counter value 305 and based on the second cumulated counter value 305, in particular based on the difference of the first cumulated counter value 305 and the second cumulated counter value 305. The digital loop filter 401 may comprise one or more digital integrators 222 which are configured to integrate the cumulated counter values provided by the one or more counters 321.

Hence, an audio amplifier circuit 400 is described, which comprises a feedback loop that can be implemented to a large extent using digital circuitry (apart from the one or more voltage or current controlled oscillators 320), thereby providing a power and area efficient audio amplifier circuit.

The oscillator frequency is preferably by a factor of 2 or more (notably 5 or more, or 10 or more) higher than the sampling frequency of the error signal 303, thereby enabling a particularly precise integration of the error signal 303.

The reference PWM unit 310 and the drive PWM unit 110, 140 typically each comprise a buffer for generating the respective PWM signal 302, 131, 132. The buffers of the reference PWM unit 310 and of the drive PWM unit 110, 140 preferably have the same amplification, thereby enabling a precise compensation of the distortions and/or noise caused by the audio amplifier circuit 100.

The audio amplifier circuit 400 may comprise a low pass filter (e.g. with one or more capacitors) configured to filter the error signal 303, thereby providing a filtered error signal to the voltage or current controlled oscillator 320 for adapting the oscillator frequency. By doing this, the robustness of the feedback loop may be increased.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiment outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. An audio amplifier circuit comprising:
a reference PWM unit configured to generate a reference PWM signal based on a to-be-rendered audio signal;
a drive PWM unit configured to generate a drive PWM signal for driving a speaker based on a corrected signal; wherein the corrected signal is dependent on the to-be-rendered audio signal;
an oscillator which is configured to adapt an oscillator frequency in dependence of an error signal; wherein the error signal is dependent on the reference PWM signal and on the drive PWM signal;
a counter configured to determine a cumulated counter value based on oscillator cycles of the voltage or current controlled oscillator; and
a digital loop filter configured to generate a correction signal for determining the corrected signal, based on the cumulated counter value.

2. The audio amplifier circuit of claim 1, wherein
the audio amplifier circuit is configured to provide a digital input signal at a sampling frequency and at an amplifier resolution for the to-be-rendered audio signal;
the reference PWM unit is configured to generate the reference PWM signal based on the digital input signal; and
the audio amplifier circuit comprises a correction unit which is configured to determine the corrected signal based on the correction signal and based on the digital input signal.

3. The audio amplifier circuit of claim 2, wherein the correction unit is configured to determine the corrected signal based on a sum or a difference of the correction signal and the digital input signal.

4. The audio amplifier circuit of claim 2, wherein the audio amplifier circuit comprises:
a sample-and-hold unit configured to generate a sampled signal based on the to-be-rendered audio signal, wherein the sampled signal exhibits the sampling frequency; and
a sigma-delta converter configured to generate the digital input signal based on the sampled signal.

5. The audio amplifier circuit of claim 2, wherein
the to-be-rendered audio signal exhibits a resolution which is at least two times higher than the amplifier resolution; and
the sampling frequency of the digital input signal is at least two times higher than the frequency that the to-be-rendered audio signal is sampled at.

6. The audio amplifier circuit of claim 1, wherein
the audio amplifier circuit comprises a quantization unit configured to generate a quantized signal based on the corrected signal;
the quantized signal is sampled at a sampling frequency and has an amplifier resolution; and
the drive PWM unit is configured to generate the drive PWM signal based on the quantized signal.

7. The audio amplifier circuit of claim 1, wherein the audio amplifier circuit comprises a combination unit configured to determine the error signal based on the reference PWM signal and based on the drive PWM signal.

8. The audio amplifier circuit of claim 1, wherein the audio amplifier circuit comprises a low pass filter configured to filter the error signal, thereby providing a filtered error signal to the oscillator for adapting the oscillator frequency.

9. The audio amplifier circuit of claim 1, wherein the digital loop filter comprises one or more digital integrators configured to integrate the cumulated counter value provided by the counter.

10. The audio amplifier circuit of claim 1, wherein
the reference PWM unit and the drive PWM unit each comprise a buffer for generating the respective PWM signal; and
the buffers of the reference PWM unit and of the drive PWM unit have the same amplification.

11. The audio amplifier circuit of claim 1, wherein
the reference PWM unit is configured to generate a differential reference PWM signal;
the drive PWM unit is configured to generate a differential drive PWM signal;
the error signal is a differential signal comprising a first component and a second component; and
the audio amplifier circuit comprises a first oscillator and a first counter for the first component of the error signal and a second oscillator and a second counter for the second component of the error signal.

12. The audio amplifier circuit of claim 11, wherein
the first oscillator and the first counter are configured to provide a first cumulated counter value based on the first component of the error signal;
the second oscillator and the second counter are configured to provide a second cumulated counter value based on the second component of the error signal; and
the loop filter is configured to generate the correction signal based on the first cumulated counter value and based on the second cumulated counter value.

13. The audio amplifier circuit of claim 12, wherein the loop filter is configured to generate the correction signal based on a difference of the first cumulated counter value and the second cumulated counter value.

14. The audio amplifier circuit of claim 1, wherein the oscillator frequency is by a factor of 2 or more higher than a sampling frequency of the error signal.

15. A method for driving a speaker; the method comprising:
generating a reference PWM signal based on a to-be-rendered audio signal using a reference PWM unit;
generating a drive PWM signal for driving the speaker based on a corrected signal using a drive PWM unit; wherein the corrected signal is dependent on the to-be-rendered audio signal;
adapting an oscillator frequency of an oscillator in dependence of an error signal;
wherein the error signal is dependent on the reference PWM signal and on the drive PWM signal;
determining a cumulated counter value based on oscillator cycles of the oscillator using a counter; and
generating a correction signal for determining the corrected signal, based on the cumulated counter value, using a loop filter.

16. The method of claim 15, further comprising:
providing a digital input signal at a sampling frequency and at an amplifier resolution for the to-be-rendered audio signal; and
determining the corrected signal based on the correction signal and based on the digital input signal;
wherein generating the reference PWM signal comprises generating the reference PWM signal based on the digital input signal.

17. The method of claim 16, wherein determining the corrected signal comprises determining the corrected signal based on a sum or a difference of the correction signal and the digital input signal.

18. The method of claim 16, further comprising:
generating, using a sample-and-hold unit, a sampled signal based on the to-be-rendered audio signal; wherein the sampled signal exhibits the sampling frequency; and
generating, using a sigma-delta converter, the digital input signal based on the sampled signal.

19. The method of claim 16, wherein
the to-be-rendered audio signal exhibits a resolution which is at least two times higher than the amplifier resolution; and
the sampling frequency of the digital input signal is at least two times higher than the frequency that the to-be-rendered audio signal is sampled at.

20. The method of claim 15, further comprising generating, using a quantization unit, a quantized signal based on the corrected signal;
wherein
the quantized signal is sampled at a sampling frequency and has an amplifier resolution; and
generating the drive PWM signal comprises generating the drive PWM signal based on the quantized signal.
